(19) United States
(12) Patent Application Publication
(10) Pub. No.: US 2025/0243580 A1
(43) Pub. Date: Jul. 31, 2025

(54) SUBSTRATE PROCESSING APPARATUS, EXHAUST SYSTEM AND METHOD OF MANUFACTURING SEMICONDUCTOR DEVICE

(71) Applicant: Kokusai Electric Corporation, Tokyo (JP)

(72) Inventors: Ryosuke TAKAHASHI, Toyama-shi (JP); Takanori UENO, Toyama-shi (JP); Masakazu SAKATA, Toyama-shi (JP)

(73) Assignee: Kokusai Electric Corporation, Tokyo (JP)

(21) Appl. No.: 19/078,959

(22) Filed: Mar. 13, 2025

Related U.S. Application Data
(63) Continuation of application No. PCT/JP2023/012015, filed on Mar. 24, 2023.

(30) Foreign Application Priority Data
Sep. 14, 2022 (JP) 2022-145713

(51) Int. Cl. C23C 16/44; C23C 16/52

(52) U.S. Cl. CPC C23C 16/4405; C23C 16/4412; C23C 16/52

(57) ABSTRACT

It is possible to extend a maintenance interval for components of an exhaust system. There is provided a technique that includes: a process chamber in which a substrate is processed; an exhaust pipe through which an atmosphere of the process chamber is exhausted; a first valve provided at the exhaust pipe and configured to close a flow path within the exhaust pipe; a second valve provided downstream of the first valve and configured to adjust a flow rate of a gas flowing through the flow path within the exhaust pipe; and a gas supplier provided with an introduction port at the exhaust pipe between the first valve and the second valve and configured to be capable of supplying a predetermined gas into the exhaust pipe through the introduction port.

### CROSS-REFERENCE TO RELATED PATENT APPLICATION

This application is a bypass continuation application of PCT International Application No. PCT/JP2023/012015, filed on Mar. 24, 2023, in the WIPO, the international application being based upon and claiming the benefit of priority from Japanese Patent Application No. 2022-145713, filed on Sep. 14, 2022, in the Japanese Patent Office, the entire contents of which are hereby incorporated by reference.

### BACKGROUND

### 1. Field

The present disclosure relates to a substrate processing apparatus, an exhaust system and a method of manufacturing a semiconductor device.

### 2. Related Art

As a part of a manufacturing process of a semiconductor device, a step of processing a substrate is performed. The step may include supplying a process gas to the substrate in a process vessel and exhausting the process gas through an exhaust system provided with an exhaust structure. By performing such a step, a predetermined amount of by-products may adhere to a location such as an inner portion of the process vessel. For example, according to some related arts, a maintenance operation for the exhaust structure may be performed at a predetermined timing, such as when the predetermined amount of the by-products adheres to the exhaust structure.

### SUMMARY

According to the present disclosure, there is provided a technique capable of extending a maintenance interval for components of an exhaust system.

According to an embodiment of the present disclosure, there is provided a technique that includes: a process chamber in which a substrate is processed; an exhaust pipe through which an atmosphere of the process chamber is exhausted; a first valve provided at the exhaust pipe and configured to close a flow path within the exhaust pipe; a second valve provided downstream of the first valve and configured to adjust a flow rate of a gas flowing through the flow path within the exhaust pipe; and a gas supplier provided with an introduction port at the exhaust pipe between the first valve and the second valve and configured to be capable of supplying a predetermined gas into the exhaust pipe through the introduction port.

### BRIEF DESCRIPTION OF THE DRAWINGS

FIG. 1 is a diagram schematically illustrating a vertical cross-section of a vertical type process furnace of a substrate processing apparatus preferably used in one or more embodiments of the present disclosure.

FIG. 2 is a diagram schematically illustrating a horizontal cross-section, taken along a line A-A shown in FIG. 1, of the vertical type process furnace of the substrate processing apparatus preferably used in the embodiments of the present disclosure.

FIG. 3 is a block diagram schematically illustrating a configuration of a controller and related components of the substrate processing apparatus preferably used in the embodiments of the present disclosure.

FIG. 4 is a diagram schematically illustrating a substrate processing sequence according to the embodiments of the present disclosure.

FIG. 5 is a diagram schematically illustrating an exhaust system of the substrate processing apparatus preferably used in the embodiments of the present disclosure.

FIG. 6 is a diagram schematically illustrating another exhaust system of the substrate processing apparatus preferably used in the embodiments of the present disclosure.

### DETAILED DESCRIPTION

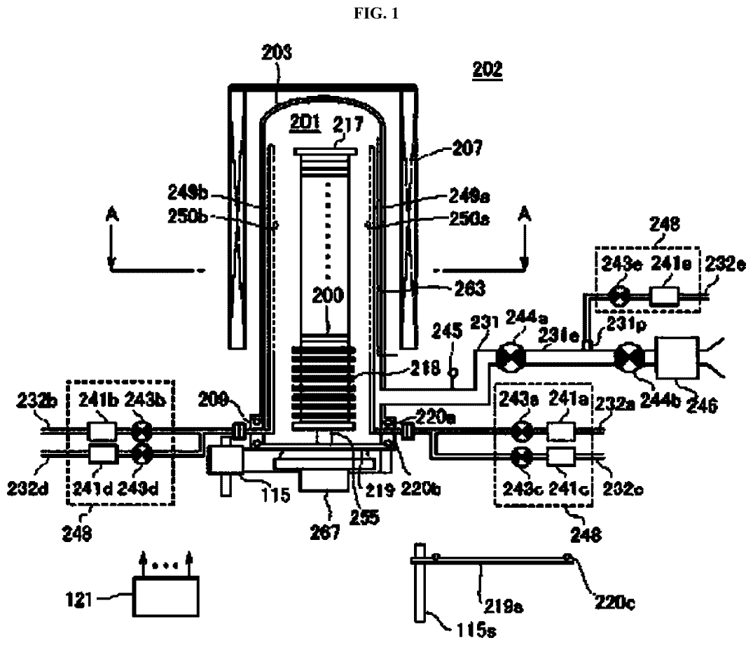

Hereinafter, one or more embodiments (also simply referred to as “embodiments”) of the technique of the present disclosure will be described in detail mainly with reference to FIGS. 1 to 5. In addition, the drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

As shown in FIG. 1, a substrate processing apparatus according to the present embodiments includes a vertical type process furnace (also simply referred to as a “process furnace”) 202. The process furnace 202 includes a heater 207 serving as a heating structure (temperature adjusting structure). The heater 207 is of a cylindrical shape, and is vertically installed while being supported by a support plate (not shown). The heater 207 also functions as an activator (also referred to as an “exciter”) capable of activating (or exciting) a gas by a heat.

A reaction tube 203 is provided in an inner side of the heater 207 to be aligned in a manner concentric with the heater 207. For example, the reaction tube 203 is made of a heat resistant material such as quartz (SiO₂) and silicon carbide (SiC). For example, the reaction tube 203 is of a cylindrical shape with a closed upper end and an open lower end. A manifold 209 is provided under the reaction tube 203 to be aligned in a manner concentric with the reaction tube 203. For example, the manifold 209 is made of a metal material such as stainless steel (SUS). For example, the manifold 209 is of a cylindrical shape with open upper and lower ends. An upper end portion of the manifold 209 is engaged with a lower end portion of the reaction tube 203 so as to support the reaction tube 203. An O-ring 220a serving as a seal is provided between the manifold 209 and the reaction tube 203. Similar to the heater 207, the reaction tube 203 is installed vertically. A process vessel (also referred to as a “reaction vessel”) is constituted mainly by the reaction tube 203 and the manifold 209. A process chamber 201 is provided in a hollow cylindrical portion of the process vessel. The process chamber 201 is configured to be capable of accommodating a plurality of wafers including a wafer 200 serving as a substrate. Hereinafter, the plurality of wafers including the wafer 200 may also be simply referred to as “wafers 200”.

Nozzles 249a and 249b are provided in the process chamber 201 so as to penetrate a side wall of the manifold 209. Gas supply pipes 232a and 232b are connected to the nozzles 249a and 249b, respectively.

Mass flow controllers (MFCs) 241a and 241b serving as flow rate controllers (flow rate control structures) and valves 243a and 243b serving as opening/closing valves are sequentially installed at the gas supply pipes 232a and 232b, respectively, in this order from upstream sides to downstream sides of the gas supply pipes 232a and 232b in a gas flow direction. Gas supply pipes 232c and 232d are connected to the gas supply pipes 232a and 232b, respectively, at downstream sides of the valves 243a and 243b. MFCs 241c and 241d and valves 243c and 243d are sequentially installed at the gas supply pipes 232c and 232d, respectively, in this order from upstream sides to downstream sides of the gas supply pipes 232c and 232d in the gas flow direction.

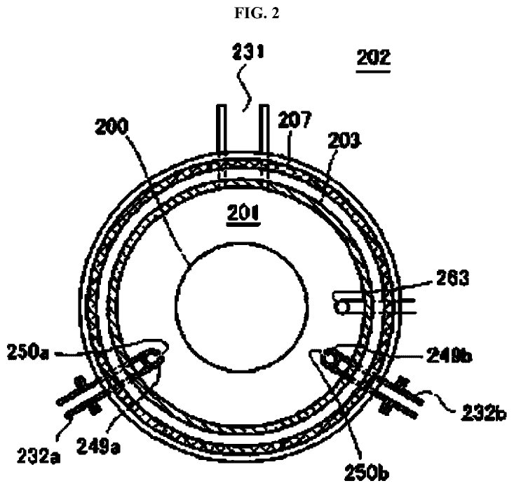

As shown in FIG. 2, each of the nozzles 249a and 249b is installed in an annular space provided between an inner wall of the reaction tube 203 and the wafers 200 when viewed from above, and extends upward from a lower portion toward an upper portion of the reaction tube 203 along the inner wall of the reaction tube 203 (that is, extends upward along an arrangement direction of the wafers 200). That is, each of the nozzles 249a and 249b is installed in a region that is located beside and horizontally surrounds a wafer arrangement region in which the wafers 200 are arranged (stacked) along the wafer arrangement region. A plurality of gas supply holes 250a and a plurality of gas supply holes 250b are provided at side surfaces of the nozzles 249a and 249b, respectively. Gases are supplied via the gas supply holes 250a and the gas supply holes 250b, respectively. The gas supply holes 250a and the gas supply holes 250b are open to face a center of reaction tube 203, and are configured such that the gases are supplied toward the wafers 200 via the gas supply holes 250a and the gas supply holes 250b, respectively. The gas supply holes 250a and the gas supply holes 250b are provided from the lower portion toward the upper portion of the reaction tube 203.

A gas containing a predetermined element (also referred to as a “primary element” or a “main element”) is supplied into the process chamber 201 through the gas supply pipe 232a provided with the MFC 241a and the valve 243a and the nozzle 249a. The gas containing the predetermined element serves as a source gas (which is one of process gases).

A second cleaning gas is supplied into the process chamber 201 through the gas supply pipe 232a provided with the MFC 241a and the valve 243a and the nozzle 249a.

A nitriding agent is supplied into the process chamber 201 through the gas supply pipe 232b provided with the MFC 241b and the valve 243b and the nozzle 249b. The nitriding agent serves as a reactive gas (which is one of the process gases). In the present specification, the term “agent” may contain at least one selected from the group of a gaseous substance and a liquid substance. Further, the liquid substance may contain a mist substance. That is, the nitriding agent may contain a gaseous substance, may contain a liquid substance such as a mist substance, or may contain both of the gaseous substance and the liquid substance. The same also applies to the following description.

An oxidizing agent is supplied into the process chamber 201 through the gas supply pipe 232b provided with the MFC 241b and the valve 243b and the nozzle 249b. The oxidizing agent serves as the reactive gas (which is one of the process gases). Hereinafter, each of the source gas, and the reactive gas may also be referred to as a “process gas”.

An inert gas is supplied into the process chamber 201 through the gas supply pipes 232c and 232d provided with the MFCs 241c and 241d and the valves 243c and 243d, respectively, the gas supply pipes 232a and 232b and the nozzles 249a and 249b. As the inert gas, for example, nitrogen (N₂) gas may be used. The inert gas may act as a purge gas or a carrier gas.

Each of a source gas supplier (which is a source gas supply system) and a second cleaning gas supplier (which is a second cleaning gas supply system) is constituted mainly by the gas supply pipe 232a, the MFC 241a and the valve 243a. The source gas supplier may serve as a part of a process gas supplier (which is a process gas supply system). A reactive gas supplier (which is a reactive gas supply system) is constituted mainly by the gas supply pipe 232b, the MFC 241b and the valve 243b. The reactive gas supplier may serve as a part of the process gas supplier. An inert gas supplier (which is an inert gas supply system) is constituted mainly by the gas supply pipes 232c and 232d, the MFCs 241c and 241d and the valves 243c and 243d. In addition, a first cleaning gas supplier (which is a first cleaning gas supply system) is constituted mainly by a gas supply pipe 232e, an MFC 241e and a valve 243c, which are described later.

Any one or the entirety of the gas suppliers described above may be embodied as an integrated gas supply system 248 in which components such as the valves 243a to 243e and the MFCs 241a to 241e are integrated. The integrated gas supply system 248 is connected to each of the gas supply pipes 232a to 232e. An operation of the integrated gas supply system 248 to supply various gases to the gas supply pipes 232a to 232e (that is, operations such as an operation of opening and closing the valves 243a to 243 and an operation of adjusting flow rates of the gases by the MFCs 241a to 241e) may be controlled by a controller 121 described later.

An exhaust pipe 231 through which an atmosphere (inner atmosphere) of the process chamber 201 is exhausted is connected to a lower side wall of the reaction tube 203. A vacuum pump 246 serving as a vacuum exhaust apparatus is connected to the exhaust pipe 231 through a pressure sensor 245, a gate valve 244a and an APC (Automatic Pressure Controller) valve 244b. The pressure sensor 245 serves as a pressure detector (pressure detection structure) configured to detect a pressure (inner pressure) of the process chamber 201. The gate valve 244a serves as a shutoff structure (hereinafter, also referred to as a “first valve structure” which is an opening/closing valve) configured to close and shut off a flow path in the exhaust pipe 231. The first valve structure may also be simply referred to as a “first valve”. The APC valve 244b serves as a pressure regulator (pressure adjusting structure) (hereinafter, also referred to as a “second valve structure” which is an adjusting valve). The second valve structure may also be simply referred to as a “second valve”. The gate valve 244a and the APC valve 244b are spaced apart from each other by a pipe length (that is, a length of a pipe in a flow direction). With such a configuration, when the gate valve 244a and the APC valve 244b are fully closed, a predetermined gas is filled in a space in the exhaust pipe 231. Specifically, since it is sufficient that the space in the exhaust pipe 231 between the gate valve 244a and the APC valve 244b is filled with the predetermined gas, the gate valve 244a and the APC valve 244b may be spaced apart from each other by, for example, 1 m or more. In the present specification, since an actual length of the exhaust pipe 231 is very long so as to exceed several tens of meters for example, a length of 4 m (4,000 mm) or less may be expressed as “close” (or “short”), and a length of 1 m or less may be expressed as “very close” (or “very short”), “close to”, “immediately nearby” or “adjacent to”. The pipe length L will be described later. With the vacuum pump 246 in operation and with the APC valve 244b open, by opening and closing the gate valve 244a, it is possible to perform a vacuum exhaust operation for the process chamber 201 or stop the vacuum exhaust operation. Further, with the vacuum pump 246 in operation and with the gate valve 244a open, by opening and closing the APC valve 244b, it is possible to perform the vacuum exhaust operation for the process chamber 201 or stop the vacuum exhaust operation. In addition, with the vacuum pump 246 in operation and with the gate valve 244a open, by adjusting an opening degree of the APC valve 244b based on pressure information detected by the pressure sensor 245, it is possible to adjust the inner pressure of the process chamber 201.

A supply port 231p serving as an introduction port (inlet) is provided at an exhaust pipe 231e (which is at least a part of the exhaust pipe 231 located downstream of the gate valve 244a and upstream of the APC valve 244b). Thereby, it is possible to supply the predetermined gas through the supply port 231p. The MFC 241e and the valve 243e are sequentially installed at the gas supply pipe 232e serving as a gas supply structure in this order from an upstream side to a downstream side of the gas supply pipe 232e in the gas flow direction. According to the present embodiments, a first cleaning gas serving as the predetermined gas is supplied into the exhaust pipe 231e and the vacuum pump 246 through the gas supply pipe 232e provided with MFC 241c and the valve 243c and the supply port 231p. In addition, although not shown, it is possible to supply the inert gas such as the N₂ gas serving as the predetermined gas.

As shown in FIG. 5, the predetermined gas such as the first cleaning gas can be supplied from the supply port 231p to the space in the exhaust pipe 231e through which the gas flows (hereinafter, the space may also be referred to as a “flow path space”), and in particular, the gate valve 244a and the APC valve 244b are arranged as close as possible to each other on the exhaust pipe 231. In other words, by setting the flow path space to be small, even when a flow rate of the first cleaning gas introduced through the supply port 231p is relatively small, it is possible to fill the flow path space with the first cleaning gas by adjusting the opening degree of the APC valve 244b, and it is also possible to efficiently remove by-products adhered to the APC valve 244b (particularly, a valve body of the APC valve 244b) while suppressing a consumption of the cleaning gas (that is, the first cleaning gas). For example, the gate valve 244a and the APC valve 244b may also be collectively referred to as a “valve structure 244”.

As shown in FIG. 5, the supply port 231p is provided in the middle (center) between a position where the gate valve 244a is disposed on the exhaust pipe 231 and a position where the APC valve 244b is disposed on the exhaust pipe 231 such that the cleaning gas introduced through the supply port 231p can be efficiently diffused throughout the flow path space. Similarly, a direction of the cleaning gas introduced through the supply port 231p and a direction of the gas flowing through the exhaust pipe 231 are set to be perpendicular (orthogonal) to each other such that the cleaning gas introduced through the supply port 231p can be efficiently diffused throughout the flow path space. The pipe length L between the gate valve 244a and the APC valve 244b is set to be 100 mm or more. A lower limit of the pipe length L (that is, for example, 100 mm) is the shortest distance to connect a cleaning gas supply line including the supply port 231p to the exhaust pipe 231. An upper limit of the pipe length L cannot be determined in general because it may vary depending on cleaning process conditions described later. However, for example, under process conditions of a first cleaning process described later which is performed in parallel with a returning to an atmospheric pressure step described later, when a diameter of the exhaust pipe 231 is set to be 200 mm, it is preferable that the upper limit of the pipe length L is set to be 4 m (4,000 mm) or less, and when the diameter of the exhaust pipe 231 is set to be 100 mm, it is preferable that the upper limit of the pipe length L is set to be 16 m (16,000 mm) or less. In addition, the upper limit of the pipe length L may also change (vary) depending on a type of a film and a type of the cleaning gas. As described above, according to the present specification, the pipe length L of 4 m or less means that the pipe length L is short.

In addition, a plurality of supply ports including the supply port 231p may be provided in the exhaust pipe 231. Hereinafter, the plurality of supply ports including the supply port 231p may also be simply referred to as “supply ports 231p”. Further, at least one among the supply ports 231p may be provided in the exhaust pipe 231e. For example, the other supply ports among the supply ports 231p may be provided at a downstream side of the APC valve 244b. An exhaust system is constituted mainly by the exhaust pipe 231, the gate valve 244a, the APC valve 244b and the pressure sensor 245. The exhaust system may further include the vacuum pump 246 and the supply port 231p connected to the exhaust pipe 231e. The exhaust system may also be referred to as an “exhaust assembly”.

A seal cap 219 serving as a first lid capable of airtightly sealing (or closing) a lower end opening of the manifold 209 (that is, an opening through which the wafer 200 is inserted and removed) is provided under the manifold 209. For example, the seal cap 219 is made of a metal material such as stainless steel (SUS), and is of a disk shape. An O-ring 220b serving as a seal is provided on an upper surface of the seal cap 219 so as to be in contact with the lower end of the manifold 209. A rotator (which is a rotating structure) 267 configured to rotate a boat 217 described later is provided under the seal cap 219. A rotating shaft 255 of the rotator 267 is connected to the boat 217 through the seal cap 219. As the rotator 267 rotates the boat 217, the wafers 200 accommodated in the boat 217 are rotated. The seal cap 219 is configured to be elevated or lowered in the vertical direction by a boat elevator 115 serving as an elevating structure provided outside the reaction tube 203. The boat elevator 115 serves as a transfer device (which is a transfer structure or a transfer system) capable of transferring (loading) the wafers 200 into the process chamber 201 and capable of transferring (unloading) the wafers 200 out of the process chamber 201 by elevating and lowering the seal cap 219. In addition, a shutter 219s serving as a second lid capable of airtightly sealing (or closing) the lower end opening of the manifold 209 is provided under the manifold 209. The shutter 219s is configured to close the lower end opening of the manifold 209 when the seal cap 219 is lowered by the boat elevator 115 and the boat 217 is unloaded out of the process chamber 201. For example, the shutter 219s is made of a metal material such as stainless steel (SUS), and is of a disk shape. An O-ring 220c serving as a seal is provided on an upper surface of the shutter 219s so as to be in contact with the lower end of the manifold 209. An opening and closing operation of the shutter 219s (such as an elevation operation and a rotation operation) is controlled by a shutter opener/closer (which is a shutter opening/closing structure) 115s.

The boat 217 (which serves as a substrate support) is configured such that the wafers 200 (for example, 25 wafers to 200 wafers) are accommodated (or supported) in the vertical direction in the boat 217 while the wafers 200 are horizontally oriented with their centers aligned with one another in a multistage manner. That is, the boat 217 is configured such that the wafers 200 are arranged in the vertical direction in the boat 217 while the wafers 200 are horizontally oriented with a predetermined interval therebetween. For example, the boat 217 is made of a heat resistant material such as quartz and SiC. For example, a plurality of heat insulation plates 218 made of a heat resistant material such as quartz and SiC are supported at a lower portion of the boat 217 in a multistage manner.

A temperature sensor 263 serving as a temperature detector is installed in the reaction tube 203. A state of electric conduction to the heater 207 is adjusted based on temperature information detected by the temperature sensor 263 such that a desired temperature distribution of a temperature (inner temperature) of the process chamber 201 can be obtained. The temperature sensor 263 is provided along the inner wall of the reaction tube 203.

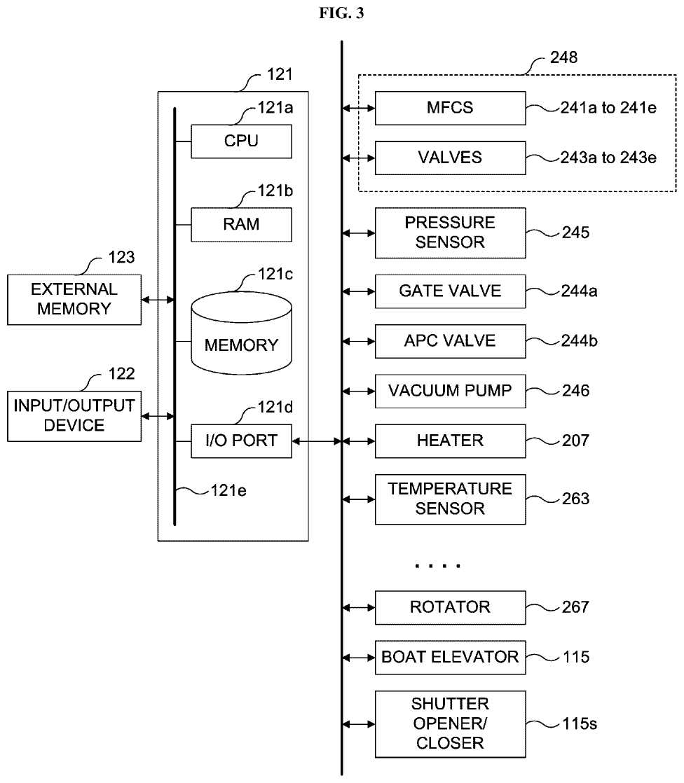

As shown in FIG. 3, the controller 121 serving as a control structure (control apparatus) is constituted by a computer including a CPU (Central Processing Unit) 121a, a RAM (Random Access Memory) 121b, a memory 121c and an I/O port (input/output port) 121d. The RAM 121b, the memory 121c and the I/O port 121d are configured to exchange data with the CPU 121a through an internal bus 121e. For example, an input/output device 122 constituted by a component such as a touch panel is connected to the controller 121.

For example, the memory 121c is configured by a component such as a flash memory and a hard disk drive (HDD). For example, a control program configured to control an operation of the substrate processing apparatus, a process recipe containing information on sequences and conditions of a substrate processing described later or a cleaning recipe containing information on sequences and conditions of the cleaning process described later may be readably stored in the memory 121c. The process recipe and the cleaning recipe are obtained by combining steps (sequences or processes) of the substrate processing and the cleaning process described later, respectively, such that the controller 121 can execute the steps to acquire predetermined results, and function as a program. Hereinafter, the process recipe, the cleaning recipe and the control program may be collectively or individually referred to as a “program”. In addition, each of the process recipe and the cleaning recipe may also be simply referred to as a “recipe”. Thus, in the present specification, the term “program” may refer to the recipe alone, may refer to the control program alone or may refer to both of the recipe and the control program. The RAM 121b functions as a memory area (work area) where a program or data read by the CPU 121a is temporarily stored.

The I/O port 121d is connected to the components described above such as the MFCs 241a to 241e, the valves 243a to 243e, the pressure sensor 245, the gate valve 244a, the APC valve 244b, the vacuum pump 246, the temperature sensor 263, the heater 207, the rotator 267, the boat elevator 115 and the shutter opener/closer 115s.

The CPU 121a is configured to read the control program from the memory 121c and execute the read control program. In addition, the CPU 121a is configured to read the recipe from the memory 121c, for example, in accordance with an operation command inputted from the input/output device 122. In accordance with contents of the read recipe, the CPU 121a may be configured to control various operations such as flow rate adjusting operations for various gases by the MFCs 241a to 241e, opening and closing operations of the valves 243a to 243e, an opening and closing operation of the gate valve 244a, an opening and closing operation of the APC valve 244b, a pressure regulating operation (pressure adjusting operation) by the APC valve 244b based on the pressure sensor 245, a start and stop operation of the vacuum pump 246, a temperature regulating operation (temperature adjusting operation) by the heater 207 based on the temperature sensor 263, an operation of adjusting a rotation and a rotation speed of the boat 217 by the rotator 267, an elevating and lowering operation of the boat 217 by the boat elevator 115 and an opening and closing operation of the shutter 219s by the shutter opener/closer 115s.

The controller 121 may be embodied by installing the above-described program stored in an external memory 123 into the computer. For example, the external memory 123 may include a magnetic disk such as the HDD, an optical disk such as a CD, a magneto-optical disk such as an MO and a semiconductor memory such as a USB memory. The memory 121c or the external memory 123 may be embodied by a non-transitory computer readable recording medium. Hereafter, the memory 121c and the external memory 123 may be collectively or individually referred to as a “recording medium”. Thus, in the present specification, the term “recording medium” may refer to the memory 121c alone, may refer to the external memory 123 alone, or may refer to both of the memory 121c and the external memory 123. Instead of the external memory 123, a communication interface such as the Internet and a dedicated line may be used for providing the program to the computer.

### (2) Substrate Processing

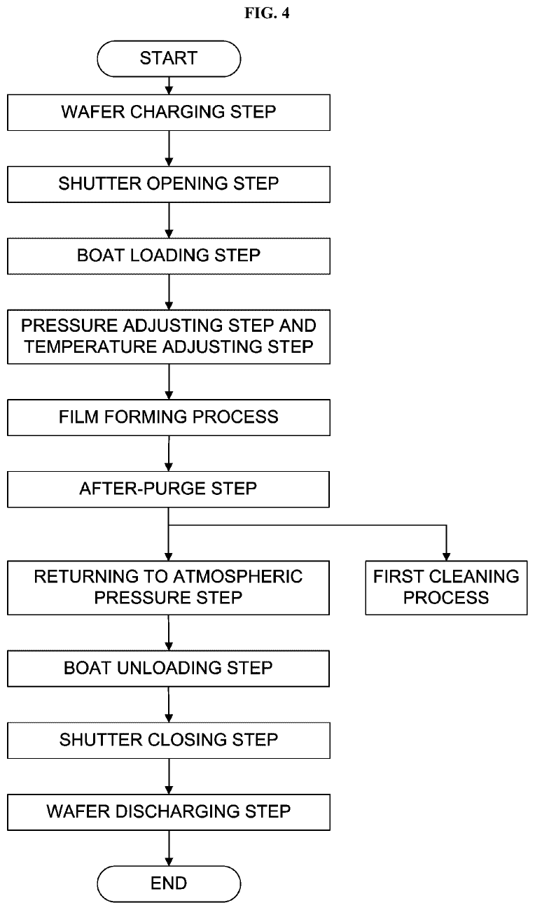

Hereinafter, an example of a sequence (that is, a film forming sequence) of forming a film on the wafer 200 serving as the substrate will be described with reference to FIG. 4. The substrate processing (which is a part of a manufacturing process of a semiconductor device) is performed by using the substrate processing apparatus described above. In the following descriptions, operations of components constituting the substrate processing apparatus are controlled by the controller 121. The same also applies to the first cleaning process and a second cleaning process described later.

According to the film forming sequence of the present embodiments, a cycle (in which a first step of supplying the process gas (source gas) to the wafer 200 in the process vessel, a second step of supplying the process gas (nitriding agent) to the wafer 200 in the process vessel, and a third step of supplying the process gas (oxidizing agent) to the wafer 200 in the process vessel are performed non-simultaneously) is performed a predetermined number of times (n times, n is an integer of 1 or more).

In the present specification, the term “wafer” may refer to “a wafer itself”, or may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself”, or may refer to “a surface of a predetermined layer (or a predetermined film) formed on a wafer”. Thus, in the present specification, “forming a predetermined layer (or a film) on a wafer” may refer to “forming a predetermined layer (or a film) directly on a surface of a wafer itself”, or may refer to “forming a predetermined layer (or a film) on a surface of another layer (or another film) formed on a wafer”. In the present specification, the terms “substrate” and “wafer” may be used as substantially the same meaning.

### Wafer Charging Step to Boat Loading Step

The wafers 200 are charged (transferred) into the boat 217 (wafer charging step). Then, the shutter 219s is moved by the shutter opener/closer 115s to open the lower end opening of the manifold 209 (shutter opening step). Thereafter, as shown in FIG. 1, the boat 217 supporting the wafers 200 is elevated by the boat elevator 115 and thereby loaded (transferred) into the process chamber 201 (boat loading step). With the boat 217 loaded, the seal cap 219 airtightly seals the lower end of the manifold 209 via the O-ring 220b.

### Pressure Adjusting Step and Temperature Adjusting Step

Then, the vacuum pump 246 vacuum-exhausts (decompresses and exhausts) the inner atmosphere of the process chamber 201 (that is, a space in which the wafers 200 are present (accommodated)) such that the inner pressure of the process chamber 201 reaches and is maintained at a desired pressure (vacuum level). When the vacuum pump 246 vacuum-exhausts the inner atmosphere of the process chamber 201, the inner pressure of the process chamber 201 is measured by the pressure sensor 245, and the APC valve 244b is feedback-controlled based on the pressure information detected by the pressure sensor 245 (pressure adjusting step). In addition, before vacuum-exhausting the inner atmosphere of the process chamber 201, the gate valve 244a is opened. Further, the heater 207 heats the process chamber 201 such that a temperature of the wafer 200 in the process chamber 201 reaches and is maintained at a desired process temperature. When the heater 207 heats the process chamber 201, the state of the electric conduction to the heater 207 is feedback-controlled based on the temperature information detected by the temperature sensor 263 such that a desired temperature distribution of the inner temperature of the process chamber 201 can be obtained (temperature adjusting step). In addition, a rotation of the wafer 200 is started by the rotator 267. The vacuum pump 246 continuously vacuum-exhausts the inner atmosphere of the process chamber 201, the heater 207 continuously heats the wafer 200 in the process chamber 201 and the rotator 267 continuously rotates the wafer 200 until at least a processing of the wafer 200 is completed. Further, in the present specification, the term “process temperature” may refer to the temperature of the wafer 200 or the inner temperature of the process chamber 201, and the term “process pressure” may refer to the inner pressure of the process chamber 201. The same also applies to the following descriptions.

### Film Forming Process

Thereafter, a film forming process is performed by sequentially performing the first step, the second step and the third step.

### First Step

In the first step, the source gas is supplied onto the wafer 200 in the process chamber 201.

Specifically, the valve 243a is opened to supply the process gas (source gas) into the gas supply pipe 232a. After a flow rate of the source gas is adjusted by the MFC 241a, the source gas whose flow rate is adjusted is supplied into the process chamber 201 through the nozzle 249a, and is exhausted through the exhaust pipe 231. Thereby, the source gas is supplied onto the wafer 200. In the present step, the valves 243c and 243d may be opened to supply the inert gas into the gas supply pipes 232c and 232d.

For example, the process conditions of the present step are as follows:

A supply flow rate of the source gas: from 1 sccm to 2,000 sccm, preferably from 10 sccm to 1,000 sccm;

A supply flow rate of the inert gas (for each gas supply pipe): from 0 sccm to 10,000 sccm;

A supply time (time duration) of supplying each gas: from 1 second to 120 seconds, preferably from 1 second to 60 seconds;

A process temperature: from 250°° C. to 800° C., preferably from 400° C. to 700° C.; and

A process pressure: from 1 Pa to 2,666 Pa, preferably from 67 Pa to 1,333 Pa.

Further, in the present specification, a notation of a numerical range such as “from 1 sccm to 2,000 sccm” means that a lower limit and an upper limit are included in the numerical range. Therefore, for example, a numerical range “from 1 sccm to 2,000 sccm” means a range equal to or higher than 1 sccm and equal to or less than 2,000 sccm. The same also applies to other numerical ranges described in the present specification. Further, when a supply flow rate of a substance (gas) is zero (0) sccm, it refers to a case where the substance is not supplied. The same also applies to the following descriptions.

By supplying the source gas to the wafer 200 in accordance with the process conditions described above, a layer containing the predetermined element (that is, a first layer) is formed on an uppermost surface (top surface) of the wafer 200.

After the first layer is formed on the wafer 200, the valve 243a is closed to stop a supply of the source gas into the process chamber 201. Then, the inner atmosphere of the process chamber 201 is vacuum-exhausted to discharge (or remove) a substance such as the gas (source gas) remaining in the process chamber 201 out of the process chamber 201. Further, when vacuum-exhausting the inner atmosphere of the process chamber 201, the valves 243c and 243d are opened to supply the inert gas into the process chamber 201. The inert gas serves as the purge gas. As the purge gas, for example, instead of or in addition to the N₂ gas, a rare gas such as argon (Ar) gas, helium (He) gas, neon (Ne) gas and xenon (Xe) gas may be used. As the inert gas, one or more of the gases exemplified above may be used.

The same also applies to the second step described below.

### Second Step

After the first step is completed, the process gas (reactive gas) (that is, the nitriding agent) is supplied onto the wafer 200 in the process chamber 201, that is, onto the first layer formed on a surface of the wafer 200.

Specifically, in the present step, opening and closing controls for the valves 243b, 243c and 243d can be performed in the same manners as those for the valves 243a, 243c and 243d in the first step. After a flow rate of the reactive gas is adjusted by the MFC 241b, the reactive gas whose flow rate is adjusted is supplied into the process chamber 201 through the nozzle 249b, and is exhausted through the exhaust pipe 231. Thereby, the reactive gas (nitriding agent) is supplied onto the wafer 200.

For example, the process conditions of the present step are as follows:

A supply flow rate of the reactive gas: from 100 sccm to 10,000 sccm;

A process pressure: from 1 Pa to 4,000 Pa, preferably from 1 Pa to 3,000 Pa.

The other process conditions of the present step may be set to be substantially the same as those of the first step described above.

By supplying the reactive gas to the wafer 200 in accordance with the process conditions described above, it is possible to modify (for example, nitride) at least a part of the first layer formed on the wafer 200 in the first step. By modifying the first layer in a manner described above, a second layer is formed on the wafer 200.

After the second layer is formed on the wafer 200, the valve 243b is closed to stop a supply of the reactive gas (nitriding agent) into the process chamber 201. Then, in accordance with the same process procedures as in the first step, a substance such as the gas (reactive gas) remaining in the process chamber 201 is discharged (removed) out of the process chamber 201.

### Third Step

After the second step is completed, the reactive gas (that is, the oxidizing agent) is supplied onto the wafer 200 in the process chamber 201, that is, onto the second layer formed on the surface of the wafer 200.

Specifically, in the present step, the opening and closing controls for the valves 243b, 243c and 243d can be performed in the same manners as those for the valves 243a, 243c and 243d in the first step. After a flow rate of the reactive gas is adjusted by the MFC 241b, the reactive gas whose flow rate is adjusted is supplied into the process chamber 201 through the nozzle 249b, and is exhausted through the exhaust pipe 231. Thereby, the reactive gas (oxidizing agent) is supplied onto the wafer 200.

For example, the process conditions of the present step are as follows:

A supply flow rate of the reactive gas: from 100 sccm to 10,000 sccm;

A process pressure: from 1 Pa to 4,000 Pa, preferably from 1 Pa to 3,000 Pa.

The other process conditions of the present step may be set to be substantially the same as those of the first step described above.

By supplying the reactive gas to the wafer 200 in accordance with the process conditions described above, it is possible to modify (for example, oxidize) at least a part of the second layer formed on the wafer 200 in the second step. By modifying the second layer in a manner described above, for example, a silicon oxynitride layer (SiON layer) serving as a third layer is formed on the wafer 200.

After the third layer is formed on the wafer 200, the valve 243b is closed to stop a supply of the reactive gas (oxidizing agent) into the process chamber 201. Then, in accordance with the same process procedures as in the first step, a substance such as the gas (reactive gas) remaining in the process chamber 201 is discharged (removed) out of the process chamber 201.

### Performing Predetermined Number of Times

By performing the cycle (in which the first step, the second step and the third step mentioned above are performed non-simultaneously, that is, in a non-synchronized manner) a predetermined number of times (n times, wherein n is an inter of 1 or more), it is possible to form a film with a predetermined composition and a predetermined thickness on the wafer 200. It is preferable that the cycle described above is repeatedly performed a plurality number of times. That is, it is preferable that the cycle is repeatedly performed a plurality number of times until a thickness of the film formed by stacking the third layer reaches a desired thickness while a thickness of the third layer formed per each cycle is smaller than the desired thickness.

### After-Purge Step and Returning to Atmospheric Pressure Step

After the film forming process is completed, the inert gas is supplied into the process chamber 201 through each of the gas supply pipes 232c and 232d, and then is exhausted through the exhaust pipe 231. Thereby, the inner atmosphere of the process chamber 201 is purged with the inert gas. As a result, a substance such as a residual gas remaining in the process chamber 201 and reaction by-products remaining in the process chamber 201 can be removed from the process chamber 201 (after-purge step). After the inner atmosphere of the process chamber 201 is replaced with the inert gas (substitution by inert gas), the APC valve 244b is fully closed. Thereafter, the inner pressure of the process chamber 201 is returned to the normal pressure (atmospheric pressure) by continuously supplying the inert gas into the process chamber 201 (returning to atmospheric pressure step).

### Boat Unloading Step to Wafer Discharging Step

Thereafter, the seal cap 219 is lowered by the boat elevator 115 and the lower end of the manifold 209 is opened. Then, the boat 217 with the wafers 200 (which are processed and supported in the boat 217) is unloaded (transferred) out of the reaction tube 203 through the lower end of the manifold 209 (boat unloading step). After the boat 217 is unloaded, the shutter 219s is moved such that the lower end opening of the manifold 209 is sealed by the shutter 219s through the O-ring 220c (shutter closing step). Then, the wafers 200 (which are processed) are discharged (transferred) from the boat 217 unloaded out of the reaction tube 203 (wafer discharging step).

### (3) First Cleaning Process

When the substrate processing (batch processing) (that is, the film forming process) mentioned above is performed, the by-products adhere to at least an inside (inner portion) of the exhaust system. That is, the by-products adhere to locations such as an inner wall of the exhaust pipe 231 including the exhaust pipe 231e, a surface of the APC valve 244b and surfaces of components (structures) inside the vacuum pump 246.

When the batch processing is repeatedly performed while the by-products adhere to the inner portion of the exhaust system, the by-products may be fixed depending on the number of executions of batch processing. The by-products fixed as described above tend to be difficult to be etched even when the cleaning gas is supplied to the inner portion of the exhaust system, and tend to be difficult to be removed from the inner portion of the exhaust system. In particular, a butterfly type APC valve (which is mainly used when the diameter of the exhaust pipe 231 is within a range from 100 mm to 200 mm) cannot be closed due to an adhesion of the by-products. In such a case, an error signal (alarm) is issued, and a maintenance operation is performed accordingly. According to the present embodiments, therefore, the inner portion of the exhaust system is cleaned by directly supplying the cleaning gas to the exhaust system without passing through the process vessel after several batches of the film forming process mentioned above are performed, preferably after each batch of the film forming process mentioned above is performed, that is, before the by-products are fixed to the inner portion of the exhaust system. The number of executions of batch processing may refer to the number of times the substrate processing from the wafer charging step to the wafer discharging step is performed. In the present specification, such a cleaning process performed on the inner portion of the exhaust system may also be referred to as the “first cleaning process”.

When cleaning the exhaust system (that is, when performing the first cleaning process), with the gate valve 244a fully closed, the valve 243e is opened to supply the first cleaning gas into the flow path space formed in the gas supply pipe 232e. After the flow rate of the first cleaning gas is adjusted by the MFC 241e, the first cleaning gas whose flow rate is adjusted is supplied into an inside (inner portion) of the exhaust pipe 231 including the exhaust pipe 231e and the inner portion of the vacuum pump 246 through the supply port 231p with the valve body of the APC valve 244b adjusted. In particular, the first cleaning gas comes into contact with the locations such as the inner wall of the exhaust pipe 231e, the surface of the APC valve 244b and the surfaces of the structures inside the vacuum pump 246. In such a state, a thermochemical reaction (etching reaction) occurs between the first cleaning gas and the by-products, and the by-products are removed from the exhaust system. In addition, when performing such a process, the vacuum pump 246 may be stopped or operated.

In addition, when performing such a process mentioned above, the opening degree of the APC valve 244b is fixed (that is, a constant pressure can be maintained) at a predetermined value while the first cleaning gas is being supplied through the supply port 231p to achieve an exhaust conductance sufficient to fill the flow path space with the first cleaning gas. As a result, since the APC valve 244b remains unmoved, the first cleaning gas can be brought into uniform contact with the entire surface of the APC valve 244b. Thereby, it is possible to efficiently remove the by-products adhered to the APC valve 244b (in particular, the valve body of the APC valve 244b) by the first cleaning gas.

In addition, as conditions for filling the flow path space with the cleaning gas, a condition that the valve body is fully closed (that is, the opening degree is 0%) is desirable as the smallest condition. Thereby, it is possible to provide the flow path space as a closed space which is closed not only from one side of the exhaust pipe 231 directed to the process chamber 201 but also from the other side of the exhaust pipe 231 directed to the vacuum pump 246. In addition, since the cleaning gas can come into contact with the APC valve 244b, it is possible to remove the by-products adhered to the APC valve 244b.

The butterfly type APC valve used in the present embodiments cannot be completely closed (that is, the opening degree is 0%) due to its structure. However, the smallest condition for the opening degree of the valve body capable of filling the flow path space with the cleaning gas is a condition that the opening degree of the valve body is set to 0% (fully closed). Such a state is shown in FIG. 5 as a valve state V0. In addition, preferably, the largest condition for the opening degree of the valve body is a condition that a flow of the cleaning gas introduced through the supply port 231p does not hit the APC valve 244b (in particular, a back surface of the valve body). In the present embodiments, a valve state V1 shown in FIG. 5 indicates that an allowable range for a valve rotation angle to fill the flow path space with the cleaning gas is up to 45° with respect to the flow direction in the exhaust pipe 231. In addition, according to the present embodiments, the cleaning gas introduced through the supply port 231p is not directly ejected against the back surface of the valve body until the valve rotation angle reaches 15°. In other words, the valve rotation angle for filling the flow path space with the cleaning gas is 0° or more and 45° or less, preferably 0° or more and 15° or less. According to the present embodiments, when the opening degree goes beyond the allowable range shown as the valve state V1 in FIG. 5, the cleaning gas may come into contact with a part of the APC valve 244b (particularly, the valve body) before filling the flow path space. As a result, that part of the APC valve 244b may be excessively cleaned, and particles may be generated.

As described above, since the butterfly type APC valve cannot be completely closed, when the opening degree is set to 0%, cleaning results may differ depending on a mechanical difference of the APC valve 244b. Specifically, in order to operate the valve body, a gap is required between the inner wall of the exhaust pipe 231 and both ends of the valve body when the opening degree is set to 0%, and it is almost difficult to maintain the gap constant. Therefore, as a condition for the opening degree of the APC valve 244b capable of filling the flow path space with the cleaning gas, by setting the opening degree to 0% or more and a few percent or less, it is possible to greatly reduce the mechanical difference. For example, the opening degree is set to be greater than 2% and equal to or less than 4%. In addition, according to the present embodiments, the opening degree (or the valve rotation angle) of the APC valve 244b is determined in accordance with a volume of the flow path space and the flow rate of the cleaning gas. Therefore, it goes without saying that the above-mentioned conditions for the opening degree (or the valve rotation angle) are just examples.

The first cleaning process is performed more frequently than the second cleaning process described later. For example, a frequency of performing the first cleaning process is set to several batches as described above, preferably one batch, and a frequency of performing the second cleaning process is set to from 300 batches to 500 batches. By performing the first cleaning process at such a high frequency, it is possible to etch the by-products in a poor state before the by-products adhere (or are fixed) to the components (structures) in the exhaust system. In addition, it is possible to easily and reliably remove the by-products adhered to the components in the exhaust system from inside the exhaust system, that is, it is possible to efficiently and effectively remove the by-products.

The first cleaning process is preferably performed during a period after the film forming process is completed and before a subsequent film forming process is started. In other words, the first cleaning process is preferably performed while the batch processing is being performed. As described above, by performing the first cleaning process promptly after the film forming process is completed and before the by-products adhered to the inner portion of the exhaust system are fixed, it is possible to more reliably remove the by-products from inside the exhaust system.

The first cleaning process may be performed with the wafer 200 accommodated in the process vessel. Specifically, the first cleaning process may be performed during a period after the wafer 200 is accommodated in the process vessel and before the film forming process is started (that is, a period after loading the boat 217 and before performing the film forming process). In addition, the first cleaning process may be performed during a period after the film forming process is completed and before the wafer 200 (to which the film forming process is performed) is transferred out of the process vessel (that is, a period after performing the film forming process and before unloading the boat 217). In addition, the film forming process may be performed while performing the first cleaning process. Thereby, it is possible to improve the throughput.

In addition, the first cleaning process may be performed after the film forming process is completed and the wafer 200 (to which the film forming process is performed) is unloaded out of the process vessel (that is, when the wafer 200 is not accommodated in the process vessel). Specifically, the first cleaning process may be performed during a period after the wafer 200 (to which the film forming process is performed) is unloaded (discharged) out of the process vessel and before a subsequent wafer 200 to be processed in a subsequent film forming process is accommodated in the process vessel (that is, a period after discharging the wafer 200 and before charging the subsequent wafer 200). When the first cleaning process is performed during the period after discharging the wafer 200 and before charging the subsequent wafer 200, it is possible to effectively utilize a waiting period between film forming processes (for example, a period for discharging the wafer 200 and charging the subsequent wafer 200).

As described above, the first cleaning process may be performed in a case where the wafer 200 is accommodated in the process vessel or in a case where the wafer 200 is not accommodated in the process vessel. In either of such cases, the first cleaning process is performed without opening the lower end opening of the manifold 209, and with the manifold 209 sealed with a lid such as the seal cap 219 and the shutter 219s. In addition, in either of these cases, the first cleaning process is performed in a state where an exhaust valve (that is, the gate valve 244a) provided at an upstream side of the supply port 231p of the exhaust pipe 231e is fully closed. By performing the first cleaning process with the gate valve 244a fully closed, it is possible to prevent the cleaning gas supplied to the exhaust system from flowing back into the process vessel. In addition, by performing the first cleaning process with the lower end opening of the manifold 209 sealed, it is possible to prevent the cleaning gas from being discharged (leaked) outside the process vessel even when the cleaning gas supplied to the exhaust system flows back into the process vessel. By performing opening/closing controls (safety controls) for the lower end opening of the manifold 209 and the APC valve 244b in a dual manner as described above, it is possible to increase a safety of the first cleaning process.

As shown in FIG. 4, according to the substrate processing sequence of the present embodiments, the first cleaning process is started after the after-purge step mentioned above is completed, and is finished before the boat unloading step is started. That is, the first cleaning process is performed in parallel with the returning to the atmospheric pressure step. In such a case, since the first cleaning process is started promptly after the film forming process is completed, it is possible to easily and reliably remove the by-products from inside the exhaust system. In addition, at a timing when the first cleaning process is started, that is, when the returning to the atmospheric pressure step is started, the gate valve 244a is fully closed as described above, and the lower end opening of the manifold 209 (the seal cap 219) is sealed. Thereby, it is possible to perform the first cleaning process safely.

For example, the process conditions of the present process are as follows:

A supply flow rate of the first cleaning gas: from 3,000 sccm to 6,000 sccm;

A supply time (time duration) of supplying the first cleaning gas: from 3 minutes to 10 minutes;

A temperature (inner temperature) of the exhaust system: from 50° C. to 100° C.; and

A pressure (inner pressure) of the exhaust system: from 1,330 Pa (10 Torr) to 101,300 Pa (atmospheric pressure).

### (4) Second Cleaning Process

When the substrate processing (batch processing) (that is, the film forming process) mentioned above is repeatedly performed, deposits including the film may accumulate inside the process vessel, for example, on the inner wall of the reaction tube 203, surfaces of the nozzles 249a and 249b and a surface of the boat 217. That is, the deposits including the film adhere to and accumulate on surfaces of the components (structures) inside the process chamber 201 which is heated. When an amount of the deposits (that is, an accumulated thickness of the film) reaches a predetermined amount (thickness) before the deposits peel off or fall off, an inside (inner portion) of the process vessel is cleaned. In the present specification, such a process performed on the process vessel may also be referred to as the “second cleaning process”. Hereinafter, an example of the second cleaning process in the present embodiments will be described.

### Boat Loading Step

After the batch processing (that is, the substrate processing from the wafer charging step to the wafer discharging step) is performed, for example, from 300 to 500 times, the shutter 219s is moved by the shutter opener/closer 115s to open the lower end opening of the manifold 209 (shutter opening step). Thereafter, an empty boat 217 (that is, the boat 217 without accommodating the wafer 200) is elevated by the boat elevator 115, and thereby loaded (transferred) into the process chamber 201 (boat loading step). With the boat 217 loaded, the seal cap 219 airtightly seals the lower end of the manifold 209 via the O-ring 220b.

### Pressure Adjusting Step and Temperature Adjusting Step

Then, the vacuum pump 246 vacuum-exhausts (decompresses and exhausts) the inner atmosphere of the process chamber 201 such that the inner pressure of the process chamber 201 reaches and is maintained at a desired pressure. The vacuum pump 246 continuously vacuum-exhausts the inner atmosphere of the process chamber 201 until at least the second cleaning process is completed. Further, the heater 207 heats the process chamber 201 such that the inner temperature of the process chamber 201 reaches and is maintained at a desired temperature. In addition, a rotation of the boat 217 is started by the rotator 267. The heater 207 continuously heats the process chamber 201 and the rotator 267 continuously rotates the boat 217 until at least a cleaning step described below is completed. However, the boat 217 may not be rotated.

### Cleaning Step

Subsequently, the second cleaning gas is supplied into the process vessel after the film forming process mentioned above is repeatedly performed. In the present step, with the valve 243b closed, the opening and closing controls of the valves 243a, 243c and 243d can be performed in the same manners as those of the valves 243a, 243c and 243d in the first step of the film forming process. After a flow rate of the second cleaning gas is adjusted by the MFC 241a, the second cleaning gas whose flow rate is adjusted is supplied into the process chamber 201 through the gas supply pipe 232a and the nozzle 249a.

When the second cleaning gas supplied into the process chamber 201 passes through the process chamber 201 and is exhausted through the exhaust pipe 231, the second cleaning gas comes into contact with the surfaces of the structures of the process chamber 201, such as the inner wall of the reaction tube 203, the surfaces of the nozzles 249a and 249b, the surface of the boat 217, an inner wall of the manifold 209 and the upper surface of the seal cap 219. In such a state, a thermochemical reaction (etching reaction) occurs between the second cleaning gas and the deposits, and as a result, the deposits are removed from the process chamber 201.

### After-Purge Step and Returning to Atmospheric Pressure Step

After the cleaning step is completed, the valve 243a is closed to stop a supply of the second cleaning gas into the process chamber 201. Then, in accordance with the same process procedures as in the after-purge step of the film forming process, the process chamber 201 is purged (after-purge step). When the process chamber 201 is purged, the inner atmosphere of the process chamber 201 may be purged intermittently by repeatedly opening and closing the valves 243c and 243d (cyclic purge step). Thereafter, the inner atmosphere of the process chamber 201 is replaced with the inert gas (substitution by inert gas), and the inner pressure of the process chamber 201 is returned to the normal pressure (atmospheric pressure) (returning to atmospheric pressure step).

### Boat Unloading Step

Thereafter, the seal cap 219 is lowered by the boat elevator 115 and the lower end of the manifold 209 is opened. Then, the empty boat 217 is unloaded (transferred) out of the reaction tube 203 through the lower end of the manifold 209 (boat unloading step). After the empty boat 217 is unloaded, the shutter 219s is moved such that the lower end opening of the manifold 209 is sealed by the shutter 219s through the O-ring 220c. When a series of the steps mentioned above is completed, the film forming process mentioned above is started again.

### Modified Example

By dividing the first cleaning process mentioned above into two cleaning steps, that is, a first exhaust cleaning step and a second exhaust cleaning step, it is possible to efficiently clean the exhaust pipe 231 (in particular, the exhaust system).

The first cleaning process mentioned above alone can remove the by-products from the exhaust system, but for example, when the first cleaning gas is supplied with the APC valve 244b open, the APC valve 244b is moved to adjust the opening degree of the APC valve 244b, and the first cleaning gas may flow through the exhaust system without uniformly contacting the entirety of the surface of the APC valve 244b. As a result, the by-products adhered to the surface of the APC valve 244b may not be uniformly removed.

In the first exhaust cleaning step, with the gate valve 244a fully closed, the valve 243e is opened to supply the first cleaning gas into the gas supply pipe 232c through the supply port 231p. Then, the flow path space in the gas supply pipe 232e is filled with the first cleaning gas while the opening degree of the APC valve 244b is fixed to a predetermined value. Thereby, the first cleaning gas can be diffused over the entirety of the surface of the APC valve 244b. As a result, it is possible to remove the by-products adhered to the surface of the APC valve 244b. In addition, the opening degree of the APC valve 244b may not be zero (that is, fully closed) as long as the first cleaning gas can fill the closed space. In addition, as the gate valve 244a and the APC valve 244b approach each other on the exhaust pipe 231, the flow path space becomes smaller. As such, the time (time duration) for supplying the first cleaning gas in the first exhaust cleaning step can be shortened. In addition, the supply ports 231p (that is, the plurality of supply ports) may be provided. Thereby, it is possible to shorten the time for the first cleaning gas to fill the flow path space. For example, when the flow rate of the first cleaning gas reaches a predetermined flow rate or when the supply time of the first cleaning gas reaches a predetermined time, the second exhaust cleaning step is performed.

In the second exhaust cleaning step, with the gate valve 244a still fully closed, the valve 243e is opened to supply the first cleaning gas into the gas supply pipe 232e through the supply port 231p. In such a state, by setting the opening degree of the APC valve 244b to be greater than a predetermined value, the APC valve 244b is opened to an extent that prevents the flow path space from being filled with the cleaning gas. In the present step, the first cleaning gas may be supplied while adjusting the opening degree of the APC valve 244b, but it is preferable to fully open the APC valve 244b. Thereby, it is possible to supply the first cleaning gas at a higher flow rate to the components in the exhaust system located downstream of the APC valve 244b. As a result, it is possible to remove the by-products adhered to the locations such as the inner wall of the exhaust pipe 231e, the surface of the APC valve 244b and the surfaces of the structures inside the vacuum pump 246. For example, the first exhaust cleaning step and the second exhaust cleaning step may be repeatedly performed.

As the cleaning gas, a gas containing a halogen element may be used, and a gas containing a fluorine element may be used. For example, a gas such as fluorine (F₂) gas, chlorine fluoride (ClF₃) gas, nitrogen fluoride (NF₃) gas and hydrogen fluoride (HF) gas may be used. As the cleaning gas, one or more of the gases exemplified above may be used.

According to the present embodiments, as the source gas, instead of or in addition to hexachlorodisilane (Si₂Cl₆, abbreviated as HCDS) gas, a chlorosilane gas such as monochlorosilane (SiH₃Cl, abbreviated as MCS) gas, dichlorosilane (SiH₂Cl₂, abbreviated as DCS) gas, trichlorosilane (SiHCl₃, abbreviated as TCS) gas, tetrachlorosilane (SiCl₄, abbreviated as STC) gas and octachlorotrisilane (Si₃Cl₈, abbreviated as OCTS) gas may be used. In addition, as the source gas, a gas such as tetrafluorosilane (SiF₄) gas, tetrabromosilane (SiBr₄) gas and tetraiodosilane (SiI₄) gas may be used. In other words, as the source gas, a halosilane gas such as the chlorosilane gas, a fluorosilane gas, a bromosilane gas and an iodosilane gas may be used. As the source gas, one or more of the gases exemplified above may be used.

In addition, as the source gas, an aminosilane gas such as bis (diethylamino) silane (SiH₂[N(C₂H₅)₂]₂, abbreviated as BDEAS) gas, bis (tertiarybutylamino) silane (SiH₂[NH(C₄H₉)]₂, abbreviated as BTBAS) gas, tris (diethylamino) silane (SiH[N(C₂H₅)₂]₃, abbreviated as 3DEAS) gas, tris (dimethylamino) silane (SiH[N(CH₃)₂]₃, abbreviated as 3DMAS) gas, tetrakis (diethylamino) silane (Si[N(C₂H₅)₂]₄, abbreviated as 4DEAS) gas and tetrakis (dimethylamino) silane (Si[N(CH₃)₂]₄, abbreviated as 4DMAS) gas may be used. As the source gas, one or more of the gases exemplified above may be used.

In addition, while the embodiments mentioned above are described by way of an example in which the N₂ gas is used as the inert gas, the technique of the present disclosure is not limited thereto. For example, as the inert gas, a rare gas such as argon (Ar) gas, helium (He) gas, neon (Ne) gas and xenon (Xe) gas may be used. As the inert gas, one or more of the gases exemplified above may be used. However, in such a case, a rare gas supply source is prepared and provided.

When the reactive gas is the nitriding agent, as the nitriding agent, instead of or in addition to ammonia gas (NH₃), a gas such as diazene (N₂H₂) gas, hydrazine (N₂H₄) gas, N₃H₈ gas and or a gas containing a compound thereof may be used. As the nitriding agent, one or more of the gases exemplified above may be used.

When the reactive gas is the oxidizing agent, as the oxidizing agent, instead of or in addition to O₂ gas, a gas such as nitrous oxide (N₂O) gas, nitric oxide (NO) gas, nitrogen dioxide (NO₂) gas, ozone (O₃) gas, hydrogen peroxide (H₂O₂) gas, water vapor (H₂O) gas, carbon monoxide (CO) gas and carbon dioxide (CO₂) gas may be used. As the oxidizing agent, one or more of the gases exemplified above may be used.

### (5) Effects According to Present Embodiments

According to the present embodiments, it is possible to obtain one or more of the following effects.
(a) By performing the first cleaning process more frequently than the second cleaning process, it is possible to etch the by-products adhered to the structures in the exhaust system in a poor state which indicates the state of the by-products before the by-products are fixed to the structures in the exhaust system. Further, it is possible to easily and reliably remove the by-products adhered to the exhaust system from the exhaust system. As a result, it is possible to reduce the maintenance frequency for the components of the exhaust system. For example, it is possible to set a frequency of performing a replacement work for the vacuum pump 246 less than a frequency of performing the second cleaning process.
(b) It is possible to more reliably obtain the effects mentioned above by performing the first cleaning process for every several batches, preferably for every batch, during the period after the film forming process is completed and before a subsequent film forming process is started.
(c) It is possible to more reliably obtain the effects mentioned above by performing the first cleaning process for every several batches, preferably for every batch, during the period after the film forming process is completed and before the wafer 200 (to which the film forming process is performed) is unloaded (discharged) out of the process vessel.
(d) In the first cleaning process, by supplying the cleaning gas to the flow path space in the exhaust pipe between a downstream location of the gate valve 244a and an upstream location of the APC valve 244b and by filling the flow path space with the cleaning gas, the cleaning gas can come into contact with the entirety of the surface of the APC valve 244b. Thereby, it is possible to remove the deposits adhered to the APC valve 244b.
(e) According to the present embodiments, the gate valve 244a and the APC valve 244b can be placed close to each other, that is, a location where the gate valve 244a is located in the exhaust pipe 231 can be placed close to (immediately close to) a location where the APC valve 244b is located in the exhaust pipe 231. Therefore, it is possible to configure the first cleaning process such that the flow path space in the exhaust pipe 231 can be easily filled with the cleaning gas introduced thereto. Therefore, with such a configuration, since the cleaning gas introduced into the flow path space can efficiently come into contact with the APC valve 244b, it is possible to remove the deposits adhered to the APC valve 244b.
(f) According to the present embodiments, the introduction port (that is, the supply port 231p) is provided. The cleaning gas is introduced into the flow path space in the exhaust pipe 231 through the supply port 231p. In other words, the cleaning gas can be supplied to the flow path space provided in the exhaust pipe between a downstream location of the gate valve 244a and an upstream location of the APC valve 244b. Therefore, by adjusting the opening degree of the APC valve 244b in the first cleaning process, it is possible to configure the flow path space such that the cleaning gas can be easily filled therein without the cleaning gas coming into direct contact with the back surface (rear surface) of the APC valve 244b. Therefore, with such a configuration, since the cleaning gas introduced into the flow path space can efficiently come into contact with the APC valve 244b, it is possible to remove the deposits adhered to the APC valve 244b.
(g) By dividing the first cleaning process into two cleaning steps, that is, the first exhaust cleaning step and the second exhaust cleaning step, it is possible to perform an efficient cleaning of the exhaust pipe 231 (in particular, the exhaust system).

### Other Embodiments of Present Disclosure

While the technique of the present disclosure is described in detail by way of the embodiments mentioned above, the technique of the present disclosure is not limited thereto. The technique of the present disclosure may be modified in various ways without departing from the scope thereof.

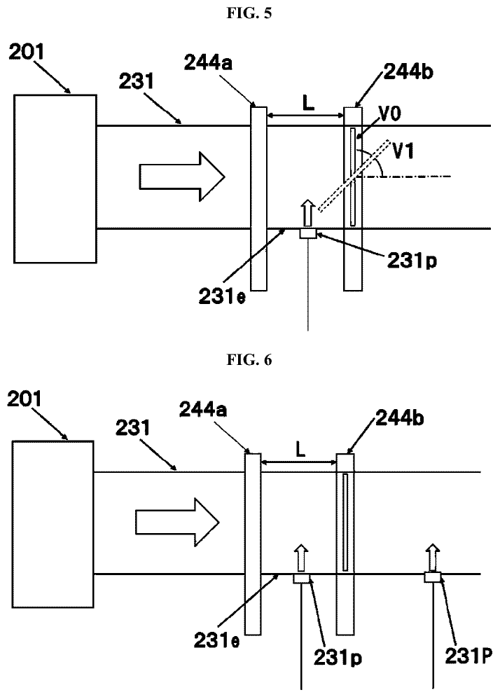

As shown in FIG. 6, a second gas structure configured to supply a predetermined gas to the exhaust pipe 231 through a supply port 231P is provided at a downstream side of the APC valve 244b. The cleaning gas can also be supplied through the supply port 231P. With such a configuration, since parameters such as a flow rate, a supply time and a type of the gas supplied to the exhaust pipe 231 through the supply port 231p and the supply port 231P can be appropriately changed, it is possible to easily and reliably remove the by-products adhered to the exhaust system from the exhaust system. Even in such a case, it is possible to obtain substantially the same effects as the embodiments described above.

In addition, a reactant contained in the reactive gas is not limited to a nitrogen-containing gas serving as the nitriding agent or an oxygen-containing gas serving as the oxidizing agent. For example, a gas reacting with the source gas to perform a film forming processing may be used to form other types of films. In addition, a film forming process using three or more types of the process gases may be performed.

For example, the embodiments mentioned above are described by way of an example in which a batch type substrate processing apparatus capable of simultaneously processing a plurality of substrates is used to form the film. However, the technique of the present disclosure is not limited thereto. For example, the technique of the present disclosure may be preferably applied when a single wafer type substrate processing apparatus capable of processing one or several substrates at a time is used to form the film. For example, the embodiments mentioned above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

The process procedures and the process conditions of each process using the substrate processing apparatuses exemplified above may be substantially the same as those of the embodiments or the modified examples mentioned above. Even in such a case, it is possible to obtain substantially the same effects as in the embodiments or the modified examples mentioned above.

For example, the embodiments mentioned above are described by way of an example in which the film forming process is performed as the substrate processing performed by the substrate processing apparatus. However, the technique of the present disclosure is not limited thereto. That is, the technique of the present disclosure can be applied not only to the film forming process but also to a process such as a process of forming an oxide film or a nitride film and a process of forming a film containing a metal. For example, the specific contents of the substrate processing are not limited to those exemplified in the embodiments mentioned above. For example, in addition to or instead of the film forming process mentioned above, the technique of the present disclosure may be applied to a process such as an annealing process, an oxidation process, a nitridation process, a diffusion process and a lithography process.

In addition, the technique of the present disclosure may also be applied to other substrate processing apparatuses such as an annealing apparatus, an oxidation apparatus, a nitridation apparatus, an exposure apparatus, a coating apparatus, a drying apparatus, a heating apparatus and a processing apparatus using plasma. Further, the technique of the present disclosure may also be applied to a case where combinations of the substrate processing apparatuses exemplified above are provided.

For example, the embodiments mentioned above are described based on a manufacturing process of a semiconductor. However, the technique of the present disclosure is not limited thereto. For example, the technique of the present disclosure may be applied another substrate processing such as a manufacturing process of a liquid crystal device, a manufacturing process of a solar cell, a manufacturing process of a light emitting device, a processing of a glass substrate, a processing of a ceramic substrate and a processing of a conductive substrate.

It is possible to substitute a constituent of one embodiment with another constituent of another embodiment, and it is also possible to add another constituent of another embodiment to one embodiment. In addition, it is possible to omit a constituent of each embodiment, to add another constituent to each embodiment and to substitute a constituent of each embodiment with another constituent. That is, the embodiments and the modified examples mentioned above may be appropriately combined. The process procedures and the process conditions of each combination thereof may be substantially the same as those of the embodiments or the modified examples mentioned above.

As described above, according to some embodiments of the present disclosure, it is possible to extend a maintenance interval for the components of the exhaust system.

What is claimed is:

1. A substrate processing apparatus comprising:
a process chamber in which a substrate is processed;
an exhaust pipe through which an atmosphere of the process chamber is exhausted;
a first valve provided at the exhaust pipe and configured to close a flow path within the exhaust pipe;
a second valve provided downstream of the first valve and configured to adjust a flow rate of a gas flowing through the flow path within the exhaust pipe; and
a gas supplier provided with an introduction port at the exhaust pipe between the first valve and the second valve and configured to be capable of supplying a predetermined gas into the exhaust pipe through the introduction port.

2. The substrate processing apparatus of claim 1, wherein the first valve is further configured to be capable of shutting off a flow path space downstream of the first valve from the exhaust pipe upstream of the first valve.

3. The substrate processing apparatus of claim 1, wherein the first valve comprises an opening/closing valve, and the second valve comprises an adjusting valve whose opening degree is controllable.

4. The substrate processing apparatus of claim 1, wherein an opening degree of the second valve is determined so as to make it possible to fill an inside of the exhaust pipe between the first valve and the second valve with the predetermined gas supplied through the introduction port.

5. The substrate processing apparatus of claim 1, wherein an opening degree of the second valve is determined so as to prevent a flow of the predetermined gas supplied to an inside of the exhaust pipe between the first valve and the second valve from directly contacting a back surface of the second valve.

6. The substrate processing apparatus of claim 5, wherein a rotation angle of the second valve is set to be 0° or more and 15° or less.

7. The substrate processing apparatus of claim 4, wherein the opening degree of the second valve is set to be greater than 0% and equal to or less than 4%.

8. The substrate processing apparatus of claim 4, wherein the opening degree of the second valve is determined in accordance with a volume of the inside of the exhaust pipe between the first valve and the second valve and a flow rate of the predetermined gas.

9. The substrate processing apparatus of claim 1, wherein an opening degree of the second valve is maintained constant while the predetermined gas is being supplied to the exhaust pipe between the first valve and the second valve.

10. The substrate processing apparatus of claim 1, wherein the introduction port is configured such that a direction of the predetermined gas and a direction of the gas flowing through the exhaust pipe are perpendicular to each other.

11. The substrate processing apparatus of claim 10, wherein the introduction port is provided at a side wall of the exhaust pipe between the first valve and the second valve.

12. The substrate processing apparatus of claim 1, wherein the first valve and the second valve are adjacent to each other.

13. The substrate processing apparatus of claim 1, wherein the predetermined gas comprises a cleaning gas.

14. The substrate processing apparatus of claim 13, wherein the gas supplier is further configured to supply the cleaning gas to the exhaust pipe between the first valve and the second valve at a predetermined flow rate or for a predetermined time.

15. The substrate processing apparatus of claim 14, wherein the second valve is further configured to increase an opening degree thereof when a flow rate of the cleaning gas reaches the predetermined flow rate or when a supply time of the cleaning gas reaches the predetermined time.

16. The substrate processing apparatus of claim 13, wherein the gas supplier is further provided with one or more introduction ports through which the cleaning gas is introduced, and the cleaning gas is capable of being supplied to the exhaust pipe between the first valve and the second valve through the introduction port and the one or more introduction ports.

17. The substrate processing apparatus of claim 1, wherein a pipe length between the first valve and the second valve is set so as to make it possible to connect a gas supply line provided with the introduction port to the exhaust pipe between the first valve and the second valve.

18. The substrate processing apparatus of claim 1, further comprising
a controller configured to be capable of controlling a type of the predetermined gas, a flow rate of the predetermined gas and a supply time of the predetermined gas supplied through the gas supplier.

19. An exhaust system comprising:
an exhaust pipe through which an atmosphere of a process chamber is exhausted;
a first valve provided at the exhaust pipe and configured to close a flow path within the exhaust pipe;
a second valve provided downstream of the first valve and configured to adjust a flow rate of a gas flowing through the flow path within the exhaust pipe; and
a gas supplier provided with an introduction port at the exhaust pipe between the first valve and the second valve and configured to be capable of supplying a predetermined gas into the exhaust pipe through the introduction port.

20. A method of manufacturing a semiconductor device, comprising:
processing a substrate arranged in a process chamber while exhausting a gas by an exhaust system, wherein the exhaust system comprises:
an exhaust pipe through which an atmosphere of the process chamber is exhausted;
a first valve provided at the exhaust pipe and configured to close a flow path within the exhaust pipe;
a second valve provided downstream of the first valve and configured to adjust a flow rate of the gas flowing through the flow path within the exhaust pipe; and
a gas supplier provided with an introduction port at the exhaust pipe between the first valve and the second valve and configured to be capable of supplying a predetermined gas into the exhaust pipe through the introduction port.
